(19) United States
(12) Patent Application Publication
(10) Pub. No.: US 2025/0006703 A1
(43) Pub. Date: Jan. 2, 2025

(54) SEMICONDUCTOR PACKAGE

(71) Applicant: SAMSUNG ELECTRONICS CO., LTD., SUWON-SI (KR)

(72) Inventors: Dong Uk KIM, Suwon-si (KR); Heon Joo HA, Suwon-si (KR)

(21) Appl. No.: 18/626,444

(22) Filed: Apr. 4, 2024

(30) Foreign Application Priority Data
Jun. 27, 2023 (KR) 10-2023-0082494

(51) Int. Cl. H01L 25/065; H01L 23/00; H01L 23/31; H01L 23/498

(52) U.S. Cl. CPC H01L 25/0657; H01L 23/3128; H01L 23/49816; H01L 24/16; H01L 24/32; H01L 24/48; H01L 24/73; H01L 2224/16227; H01L 2224/32145; H01L 2224/48227; H01L 2224/73253; H01L 2224/73265; H01L 2225/0651; H01L 2225/06517

(57) ABSTRACT

A semiconductor package includes a package substrate. A lower chip is on the package substrate. An upper chip is on the lower chip. An input/output signal bump is between the lower chip and the package substrate and receives/outputs a signal to/from the lower chip. A wire bonding pad is on the upper chip and includes a wire connected thereto. A first input/output signal ball is on the package substrate and receives/outputs the signal to/from the lower chip and is connected to the input/output signal bump. A second input/output signal ball is on the package substrate and receives/outputs a signal to/from the upper chip and is electrically connected to the wire bonding pad. The input/output signal bump is closer to the first input/output signal ball than the second input/output signal ball. The wire bonding pad is closer to the second input/output signal ball than the first input/output signal ball.

### CROSS-REFERENCE TO RELATED APPLICATION

This application claims priority under 35 U.S.C. § 119 to Korean Patent Application No. 10-2023-0082494, filed on Jun. 27, 2023 in the Korean Intellectual Property Office, the disclosure of which is incorporated by reference in its entirety herein.

### 1. Technical Field

The present inventive concept relates to a semiconductor package.

### 2. Discussion of Related Art

In recent years there has been an increased demand for miniaturization and a lightweight of electronic components. A reduction in semiconductor packages to be mounted is necessary to provide such miniaturized and lightweight electronic components. While an area of the package for accommodating the semiconductor chips is limited, the size and the number of semiconductor chips that fit inside the package are increasing. Therefore, the semiconductor chips should be efficiently placed within the limited area of the package.

A semiconductor package using a flip-chip bonding method has advantages of providing increased electrical characteristics and a relatively low package height as compared to conventional wire bonding.

### SUMMARY

Aspects of embodiments of the present invention provide a semiconductor package having increased product reliability.

According to an embodiment of the present disclosure, a semiconductor package includes a package substrate. A lower chip is disposed on the package substrate. An upper chip is disposed on the lower chip. An input/output signal bump is disposed between the lower chip and the package substrate. The input/output signal bump receives and outputs a signal to and from the lower chip. A wire bonding pad is disposed on an upper face of the upper chip. A wire is connected to the wire bonding pad. A first input/output signal ball is disposed on a lower face of the package substrate. The first input/output signal ball receives and outputs the signal to and from the lower chip. The first input/output signal ball is connected to the input/output signal bump. A second input/output signal ball is disposed on the lower face of the package substrate. The second input/output signal ball receives and outputs a signal to and from the upper chip. The second input/output signal ball is electrically connected to the wire bonding pad. The first input/output signal ball and the second input/output signal ball are spaced apart from each other in a first direction. The input/output signal bump is disposed closer to the first input/output signal ball than the second input/output signal ball. The wire bonding pad is disposed closer to the second input/output signal ball than the first input/output signal ball in the first direction.

According to an embodiment of the present disclosure, a semiconductor package includes a package substrate. A first semiconductor chip stack is disposed on the package substrate. The first semiconductor chip stack includes a first lower chip and a first upper chip sequentially stacked. A second semiconductor chip stack is disposed on the package substrate and is spaced apart from the first semiconductor chip stack. The second semiconductor chip stack includes a second lower chip and a second upper chip sequentially stacked. A first wire bonding pad is disposed on the first upper chip. The first wire bonding pad is electrically connected to the package substrate by a wire. An input/output signal bump is disposed between the first semiconductor chip stack and the package substrate. The input/output signal bump receives and outputs input/output signals to and from the first lower chip. The package substrate includes a first input/output signal ball disposed on a lower face of the package substrate. The first input/output signal ball is electrically connected to the input/output signal bump. The package substrate further includes a second input/output signal ball disposed on the lower face of the package substrate and spaced apart from the first input/output signal ball. The second input/output signal ball is electrically connected to the wire. The first semiconductor chip stack includes a first side face facing the second semiconductor chip stack, and a second side face opposite to the first side face. The first input/output signal ball is disposed closer to the first side face than the second side face. The second input/output signal ball is disposed closer to the second side face than the first side face.

According to an embodiment of the present disclosure, a semiconductor package includes a package substrate. A first semiconductor chip stack is disposed on the package substrate. The first semiconductor chip stack includes a first lower chip and a first upper chip sequentially stacked. A second semiconductor chip stack is disposed on the package substrate and is spaced apart from the first semiconductor chip stack. The second semiconductor chip stack includes a second lower chip and a second upper chip sequentially stacked. A first wire bonding pad is disposed on the first upper chip. The first wire bonding pad is electrically connected to the package substrate by a first wire. A first input/output signal bump is disposed between the first semiconductor chip stack and the package substrate. The first input/output signal bump receives and outputs an input/output signal to and from the first lower chip. A second wire bonding pad is disposed on the second upper chip. The second wire bonding pad is electrically connected to the package substrate by a second wire. A second input/output signal bump is disposed between the second semiconductor chip stack and the package substrate. The second input/output signal bump receives and outputs an input/output signal to and from the second upper chip. A first input/output signal ball is disposed on a lower face of the package substrate. The first input/output signal ball is connected to the first input/output signal bump. A second input/output signal ball is disposed on the lower face of the package substrate. The second input/output signal ball is connected to the first wire bonding pad. A third input/output signal ball is disposed on the lower face of the package substrate. The third input/output signal ball is connected to the second input/output signal bump. A fourth input/output signal ball is disposed on the lower face of the package substrate. The fourth input/output signal ball is connected to the second wire bonding pad. A power ball is disposed on the lower face of the package substrate. The power ball provides power to the first semiconductor chip stack or the second semiconductor chip stack. A distance between the first input/output signal bump and the second input/output signal bump is less than a distance between the first wire bonding pad and the second wire bonding pad.

However, aspects of embodiments of the present disclosure are not restricted to the ones set forth herein. The above and other aspects of embodiments of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of embodiments of the present disclosure will become more apparent by describing in detail non-limiting embodiments thereof with reference to the attached drawings, in which:

FIG. 1 is a plan view for explaining a semiconductor package according to an embodiment of the present disclosure.

FIG. 2 is a plan view for explaining a semiconductor package according to an embodiment of the present disclosure.

FIG. 3 is an enlarged plan view showing a portion P1 of FIG. 2 according to an embodiment of the present disclosure.

FIG. 4 is a cross-sectional view taken along line A-A of FIG. 1 according to an embodiment of the present disclosure.

FIG. 5 is an enlarged view showing a portion P2 of FIG. 4 according to an embodiment of the present disclosure.

FIG. 6 is a diagram for explaining a semiconductor package according to an embodiment of the present disclosure.

FIG. 7 is a diagram for explaining a semiconductor package according to an embodiment of the present disclosure.

FIG. 8 is a diagram for explaining a semiconductor package according to some other embodiment of the present disclosure.

FIG. 9 is a diagram for explaining a semiconductor package according to an embodiment of the present disclosure.

FIG. 10 is a diagram for explaining a semiconductor package according to an embodiment of the present disclosure.

### DETAILED DESCRIPTION OF EMBODIMENTS

Hereinafter, embodiments according to the present disclosure will be described with reference to the accompanying drawings.

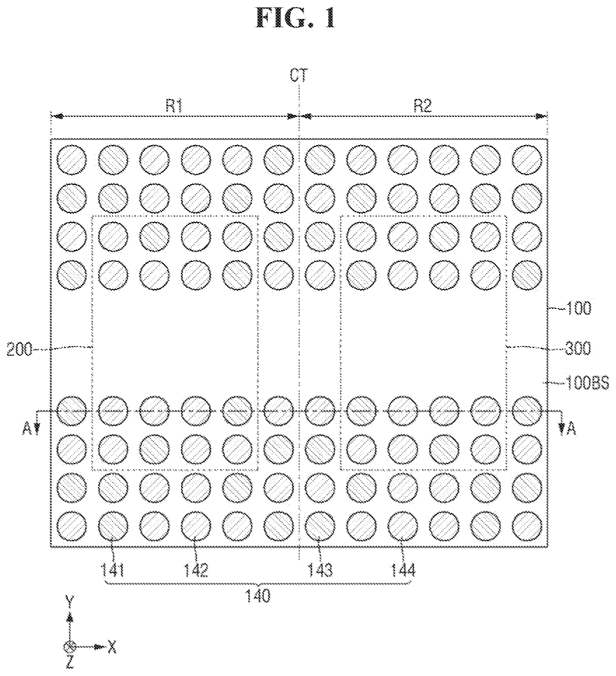

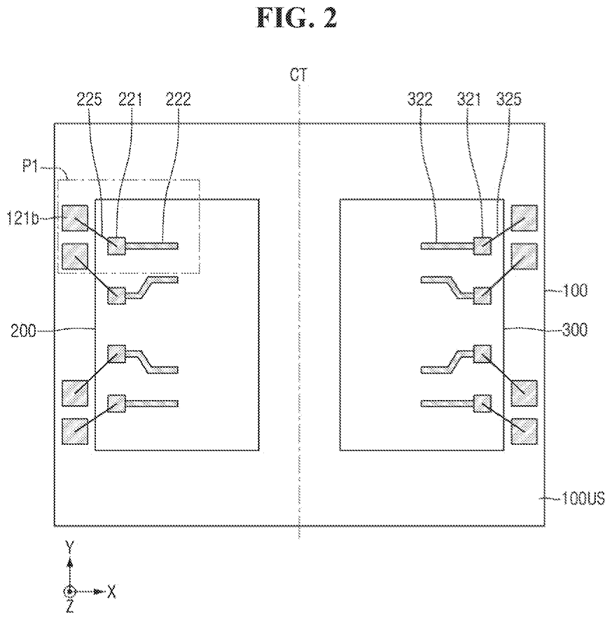

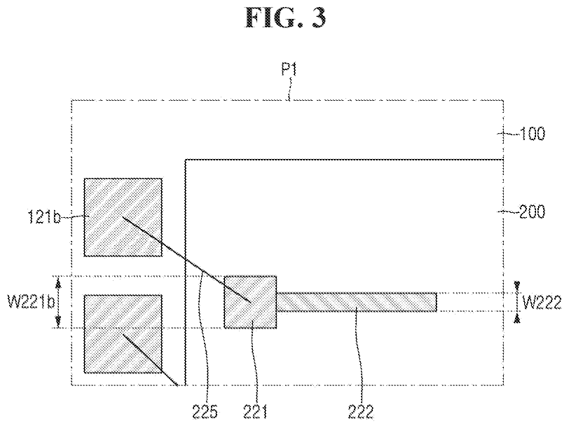

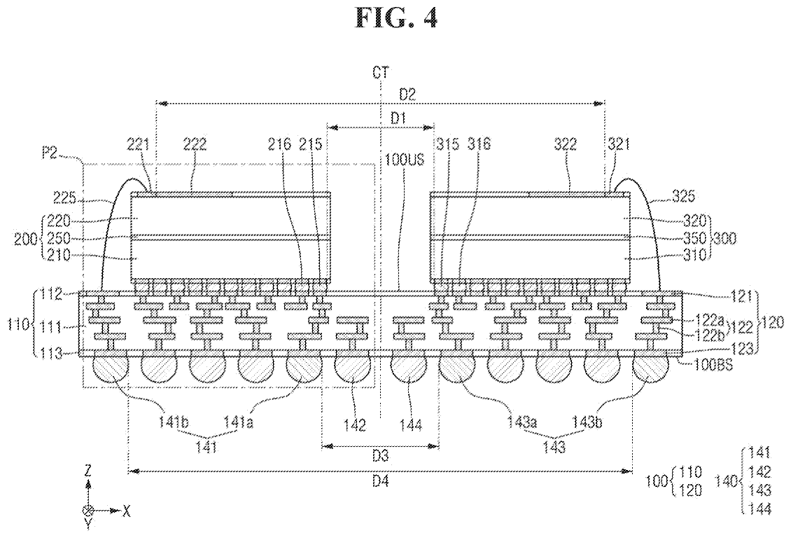

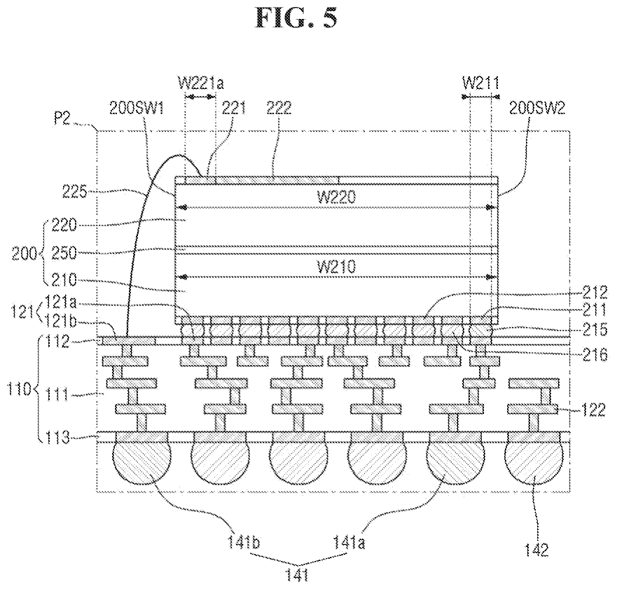

FIG. 1 is a plan view for explaining a semiconductor package according to some embodiments. FIG. 2 is a plan view for explaining a semiconductor package according to some embodiments. FIG. 3 is an enlarged view showing a portion P1 of FIG. 2. FIG. 4 is a cross-sectional view taken along line A-A of FIG. 1. FIG. 5 is an enlarged view showing a portion P2 of FIG. 4.

Referring to FIGS. 1 to 5, a semiconductor package according to some embodiments may include a package substrate 100, a first semiconductor chip stack 200, a second semiconductor chip stack 300, a first wire 225, a second wire 325, a first input/output signal bump 215, a second input/output signal bump 315, and an external connection terminal 140.

In an embodiment, the package substrate 100 may be a wiring structure for package. For example, the package substrate 100 may be a printed circuit wiring structure (PCB), a ceramic wiring structure, or the like. However, embodiments of the present disclosure are not necessarily limited thereto. For example, in some embodiments the package substrate 100 may be a wiring structure for a wafer level package (WLP) fabricated at a wafer level. The package substrate 100 may include a lower face 100BS and an upper face 100US that are opposite to each other (e.g., in the third direction Z).

The package substrate 100 may include a first region R1 and a second region R2 divided on the basis of a central portion CT. The first semiconductor chip stack 200 may be placed in the first region R1. The second semiconductor chip stack 300 may be placed in the second region R2.

In an embodiment, the package substrate 100 may include a first insulating layer 110 and a substrate wiring structure 120. In an embodiment, the first insulating layer 110 may include a first substrate 111, a first lower passivation film 113 and a first upper passivation film 112. The substrate wiring structure 120 may include a first lower pad 123, a first wiring 122 and a first upper pad 121.

In an embodiment, the first substrate 111 may be, for example, a printed circuit board (PCB) or a ceramic substrate. However, embodiments of the present disclosure are not necessarily limited thereto.

In an embodiment in which the first substrate 111 is a printed circuit board, the first insulating layer 110 may be made up of at least one material selected from phenol resin, epoxy resin, and polyimide. In an embodiment, the first insulating layer 110 may include, for example, at least one material selected from FR-4, tetrafunctional epoxy, polyphenylene ether, epoxy/polyphenylene oxide, BT (bismaleimide triazine), thermount, cyanate ester, polyimide, and liquid crystal polymer. In an embodiment, the surface of the first substrate 111 may be covered with solder resist. For example, the first lower passivation film 113 and the first upper passivation film 112 formed on the surface of the first substrate 111 may be solder resist. However, embodiments of the present disclosure are not necessarily limited thereto.

Although the first substrate 111 is shown in FIG. 4 as being a single layer, this is only for convenience of explanation and embodiments of the present disclosure are not necessarily limited thereto. For example, in an embodiment the first substrate 111 may be made up of multiple layers to form the first wiring 122 of multiple layers.

The substrate wiring structure 120 may be disposed inside the first insulating layer 110. In an embodiment, the substrate wiring structure 120 may be made up of the first wiring 122 for electrically connecting the first lower pad 123 and the first upper pad 121. The first wiring 122 may include a plurality of wiring patterns 122a and a plurality of vias 122b for connecting each wiring pattern. The first upper pad 121, the first wiring 122, and the first lower pad 123 may include a conductive material. For example, in an embodiment the first upper pad 121, the first wiring 122 and the first lower pad 123 may include gold (Au), silver (Ag), copper (Cu), nickel (Ni) or aluminum (Al).

In an embodiment, the first upper pad 121 may include a lower bump bonding pad 121a and a lower wire bonding pad 121b.

The lower bump bonding pads 121a may be disposed below the first semiconductor chip stack 200. The lower bump bonding pad 121a may overlap the first semiconductor chip stack 200 in a third direction Z. The lower bump bonding pad 121a may be in direct contact with the first input/output signal bump 215 and the first power bump 216 of the first semiconductor chip stack 200. The lower bump bonding pad 121a may be disposed below the first input/output signal bump 215 and the first power bump 216 of the first semiconductor chip stack 200. The lower bump bonding pad 121a may be electrically connected to the first input/output signal bump 215 and the first power bump 216 of the first semiconductor chip stack 200.

The lower wire bonding pad 121b may be disposed on the upper face 100US of the package substrate. For example, the lower wire bonding pads 121b may be arranged to be spaced apart from each other in a second direction Y that is perpendicular to the third direction Z. However, embodiments of the present disclosure are not necessarily limited thereto and the second direction Y may intersect the first direction X in various different angles. The lower wire bonding pad 121b may not overlap the first semiconductor chip stack 200 and the second semiconductor chip stack 300 in the third direction Z.

The lower wire bonding pad 121b may be in direct contact with the first wire 225. The lower wire bonding pad 121b may be electrically connected to the first upper wire bonding pad 221 through the first wire 225.

In an embodiment, the size of the lower bump bonding pad 121a may be less than the size of the lower wire bonding pad 121b. For example, in a first direction X that is perpendicular to both the second direction Y and the third direction Z, the width of the lower bump bonding pad 121a may be less than the width of the lower wire bonding pad 121b. However, embodiments of the present disclosure are not necessarily limited thereto. For example, in an embodiment the size of the lower bump bonding pad 121a may be greater than or equal to the size of the lower wire bonding pad 121b.

In some embodiments, an external connection terminal 140 may be disposed on the lower face 100BS of the package substrate 100. The external connection terminal 140 may be attached to the first lower pad 123. For example, in an embodiment the external connection terminal 140 may be in direct contact with the first lower pad 123. The external connection terminal 140 may be disposed below the first lower pad 123 (e.g., in the third direction Z). In an embodiment, the external connection terminal 140 may have, for example, but is not necessarily limited to, a spherical shape or an oval shape.

The external connection terminal 140 may electrically connect the substrate wiring structure 120 to an external device. Accordingly, the external connection terminal 140 may provide an electrical signal to the substrate wiring structure 120 or may provide an electrical signal provided from the substrate wiring structure 120 to the external device.

In an embodiment, the external connection terminal 140 may include a first stack input/output signal ball 141, a first stack power ball 142, a second stack input/output signal ball 143, and a second stack power ball 144.

In an embodiment, the first stack input/output signal ball 141 and the first stack power ball 142 may be placed in the first region R1. The first stack input/output signal ball 141 and the first stack power ball 142 may be disposed on the lower face 100BS of the package substrate of the first region R1. The second stack input/output signal ball 143 and the second stack power ball 144 may be disposed in the second region R2. The second stack input/output signal ball 143 and the second stack power ball 144 may be disposed on the lower face 100BS of the package substrate of the second region R2.

Input/output signals of the first semiconductor chip stack 200 may be provided to the first stack input/output signal ball 141. For example, in an embodiment a signal input to the first semiconductor chip stack 200 may be provided to the first stack input/output signal ball 141 from the outside (e.g., an external device). As another example, a signal which is output from the first semiconductor chip stack 200 may be provided to the first stack input/output signal ball 141 for sending to the external device.

In an embodiment, the first stack input/output signal ball 141 may include a first input/output signal ball 141a and a second input/output signal ball 141b. The first input/output signal ball 141a and the second input/output signal ball 141b may be spaced apart from each other in the first direction X.

In an embodiment, the first input/output signal ball 141a may be connected to the lower bump bonding pad 121a, the first input/output signal bump 215 and the first input/output bump pad 211. Input/output signals of the first lower chip 210 may be provided to the first input/output signal ball 141a. For example, data signal input to the first lower chip 210 may be provided to the first input/output signal ball 141a. As another example, data signal output from the first lower chip 210 may be provided to the first input/output signal ball 141a. As still another example, command/address signals for the first lower chip 210 may be provided to the first input/output signal ball 141a.

In an embodiment, the second input/output signal ball 141b may be connected to the lower wire bonding pad 121b, the first wire 225 and the first upper wire bonding pad 221b. Input/output signals of the first upper chip 220 may be provided to the second input/output signal ball 141b. For example, the data signal input to the first upper chip 220 may be provided to the second input/output signal ball 141b. As another example, the data signal output from the first upper chip 220 may be provided to the second input/output signal ball 141b. As still another example, command/address signal for the first upper chip 220 may be provided to the second input/output signal ball 141b.

In an embodiment, the first stack power ball 142 may be connected to the first lower chip 210 through the lower bump bonding pad 121a, the first power bump 216 and the first power bump pad 212. The first stack power ball 142 may be connected to the first upper chip 220 through the lower wire bonding pad 121b, the first wire 225 and the first upper wire bonding pad 221. For example, the first stack power ball 142 may be connected to the first upper chip 220 through the lower wire bonding pad 121b, the first wire 225 and the first upper wire bonding pad 221 to which the first stack input/output signal ball 141 is not connected.

The power of the first lower chip 210 and the first upper chip 220 may be provided to the first stack power ball 142. In an embodiment, the level of the signal provided to the first stack power ball 142 may be higher than the level of the signal provided to the first stack input/output signal ball 141.

Input/output signal of the second semiconductor chip stack 300 may be provided to the second stack input/output signal ball 143. For example, a signal input to the second semiconductor chip stack 300 may be provided to the second stack input/output signal ball 143 from the outside (e.g., an external device). As another example, the signal output from the second semiconductor chip stack 300 may be provided to the second stack input/output signal ball 143 for sending to the external device.

In an embodiment, the second stack input/output signal ball 143 may include a third input/output signal ball 143a and a fourth input/output signal ball 143b.

In an embodiment, the third input/output signal ball 143a may be connected to the lower bump bonding pad 121a and the second input/output signal bump 315. The input/output signal of the second lower chip 310 may be provided to the third input/output signal ball 143a. For example, the data signal input to the second lower chip 310 may be provided to the third input/output signal ball 143a. As another example, data signal output from the second lower chip 310 may be provided to the third input/output signal ball 143a. As still another example, command/address signal for the second lower chip 310 may be provided to the third input/output signal ball 143a.

In an embodiment, the fourth input/output signal ball 143b may be connected to the lower wire bonding pad 121b, the second wire 325, and the second upper wire bonding pad 321b. The input/output signal of the second upper chip 320 may be provided to the fourth input/output signal ball 143b. For example, data signal input to the second upper chip 320 may be provided to the fourth input/output signal ball 143b. As another example, data signal output from the second upper chip 320 may be provided to the fourth input/output signal ball 143b. As still another example, command/address signal for the second upper chip 320 may be provided to the fourth input/output signal ball 143b.

In an embodiment, the second stack power ball 144 may be connected to the second lower chip 310 through the lower bump bonding pad 121a and the second power bump 316. The second stack power ball 144 may be connected to the second upper chip 320 through the lower wire bonding pad 121b, the second wire 325 and the second upper wire bonding pad 321. For example, the second stack power ball 144 may be connected to the second upper chip 320 through the lower wire bonding pad 121b, the second wire 325, and the second upper wire bonding pad 321 to which the second stack input/output signal ball 143 is not connected.

The power of the second lower chip 310 and the second upper chip 320 may be provided to the second stack power ball 144. In an embodiment, the level of the signal provided to the second stack power ball 144 may be higher than the level of the signal provided to the second stack input/output signal ball 143.

In an embodiment, the first input/output signal ball 141a and the third input/output signal ball 143a may be disposed to be closer (e.g., in the first direction X) to the central portion CT than the second input/output signal ball 141b and the fourth input/output signal ball 143b. The first input/output signal ball 141a may be disposed to be closer (e.g., in the first direction X) to the central portion CT than the second input/output signal ball 141b. The third input/output signal ball 143a may be disposed to be closer (e.g., in the first direction X) to the central portion CT than the fourth input/output signal ball 143b.

For example, the first input/output signal ball 141a connected to the first input/output signal bump 215 may be disposed to be closer (e.g., in the first direction X) to the central portion CT than the second input/output signal ball 141b connected to the first wire 225. The third input/output signal ball 143a connected to the second input/output signal bump 315 may be disposed to be closer (e.g., in the first direction X) to the central portion CT than the fourth input/output signal ball 143b connected to the second wire 325.

In the first direction X, the first input/output signal ball 141a and the third input/output signal ball 143a may be spaced apart from each other by a third distance D3. In the first direction X, the second input/output signal ball 141b and the fourth input/output signal ball 143b may be spaced apart from each other by a fourth distance D4. In an embodiment, the third distance D3 may be less than the fourth distance D4.

The first semiconductor chip stack 200 may include a plurality of semiconductor chips. In an embodiment, the first semiconductor chip stack 200 may include a first lower chip 210 and a first upper chip 220. However, embodiments of the present disclosure are not necessarily limited thereto and the number of semiconductor chips included in the first semiconductor chip stack 200 may vary. The first lower chip 210 and the first upper chip 220 may be sequentially stacked on the package substrate 100 (e.g., in the third direction Z). The first upper chip 220 may be disposed on the first lower chip 210. For example, a lower surface of the first upper chip 220 may be disposed on an upper surface of the first lower chip 210. In an embodiment, the first semiconductor chip stack 200 may include a field programmable gate array (FPGA).

In an embodiment, the first lower chip 210 and the first upper chip 220 may include memory chips. For example, the first lower chip 210 and the first upper chip 220 may include volatile memory chips such as DRAM. However, embodiments of the present disclosure are not necessarily limited thereto.

The first semiconductor chip stack 200 may have a first side wall 200SW1 and a second side wall 200SW2. The first side wall 200SW1 and the second side wall 200SW2 may be opposite to each other (e.g., in the first direction X). The second side wall 200SW2 may face the second semiconductor chip stack 300.

The side walls of the first lower chip 210 and the first upper chip 220 may be aligned with each other. The first lower chip 210 and the first upper chip 220 may have a first side wall 200SW1 and a second side wall 200SW2. The first lower chip 210 and the first upper chip 220 may have the same width as each other (e.g., length in the first direction X). For example, the width W210 of the first lower chip and the width W220 of the first upper chip may be the same as each other.

In an embodiment, a first adhesive layer 250 may be disposed between the first lower chip 210 and the first upper chip 220 (e.g., in the third direction Z). The first adhesive layer 250 may serve to insulate the first lower chip 210 and the first upper chip 220 from each other. For example, in an embodiment the first adhesive layer 250 may be a DAF (Direct Adhesive Film).

In an embodiment, the first adhesive layer 250 may include an insulating polymer. For example, the first adhesive layer 250 may include epoxy-based resin and filler. In this case, the filler may utilize at least one or more selected from a group including silica (SiO₂), alumina (Al₂O₃), silicon carbide (SiC), barium sulfate (BaSO₄), talc, mud, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃). However, embodiments of the present disclosure are not necessarily limited thereto and the material of the filler may vary. For example, the material of the filler may include a metal substance and/or an organic substance.

In an embodiment, the first lower chip 210 may include a first input/output bump pad 211 and a first power bump pad 212. The first input/output bump pad 211 and the first power bump pad 212 may be disposed on the lower face (e.g., a bottom surface) of the first lower chip 210.

In an embodiment, a first input/output signal bump 215 and a first power bump 216 may be disposed between the first lower chip 210 and the package substrate 100. The first input/output signal bump 215 may be disposed on the first input/output bump pad 211. The first input/output signal bump 215 may be disposed between the first input/output bump pad 211 and the lower bump bonding pad 121a.

In an embodiment, the first input/output signal bump 215 may be disposed to be closer (e.g., in the first direction X) to the second side wall 200SW2 than the first side wall 200SW1 of the first semiconductor chip stack 200. However, embodiments of the present disclosure are not necessarily limited thereto. For example, in an embodiment the first input/output signal bump 215 may be disposed to be closer (e.g., in the first direction X) to the first side wall 200SW1 than the second side wall 200SW2 of the first semiconductor chip stack 200.

In an embodiment, the first input/output bump pad 211 may be in direct contact with the first input/output signal bump 215. The first input/output bump pad 211 may be electrically connected to the first input/output signal bump 215. The first input/output bump pad 211 may be electrically connected to the first input/output signal ball 141a through the first input/output signal bump 215 and the lower bump bonding pad 121a.

The first lower chip 210 may receive or output signals through the first input/output bump pad 211, the first input/output signal bump 215, the lower bump bonding pad 121a, and the first input/output signal ball 141a which are connected to each other. For example, in an embodiment the first lower chip 210 may receive or output data through the first input/output bump pad 211, the first input/output signal bump 215, the lower bump bonding pad 121a, and the first input/output signal ball 141a which are connected to each other. As another example, a command/address signal may be provided to the first lower chip 210 through the first input/output bump pad 211, the first input/output signal bump 215, the lower bump bonding pad 121a, and the first input/output signal ball 141a which are connected together.

The first power bump pad 212 may be in direct contact with the first power bump 216. The first power bump pad 212 may be electrically connected to the first power bump 216. The first power bump pad 212 may be electrically connected to the first stack power ball 142 through the first power bump 216 and the lower bump bonding pad 121a.

Power may be provided to the first lower chip 210 through the first power bump pad 212, the first power bump 216, the lower bump bonding pad 121a and the first stack power ball 142.

In an embodiment, the first upper chip 220 may include a first upper wire bonding pad 221. The first upper wire bonding pad 221 may be disposed on the upper face (e.g., a top surface) of the first upper chip 220. For example, in an embodiment the first upper wire bonding pads 221 may be disposed to be spaced apart from each other in the second direction Y on the upper face of the first upper chip 220.

In an embodiment, the first upper wire bonding pad 221 may be connected to the first wire 225. For example, in an embodiment the first wire 225 may be in direct contact with the upper face (e.g., a top surface) of the first upper wire bonding pad 221. The first upper wire bonding pad 221 may be connected to the lower wire bonding pad 121b through the first wire 225. The first upper wire bonding pad 221 may be electrically connected to the second input/output signal ball 141b through the first wire 225 and the lower wire bonding pad 121b.

In an embodiment, the first upper wire bonding pad 221 may be disposed to be closer to (e.g., in the first direction X) the first side wall 200SW1 than the second side wall 200SW2 of the first semiconductor chip stack 200. However, embodiments of the present disclosure are not necessarily limited thereto. For example, in an embodiment the first upper wire bonding pad 221 may be disposed to be closer to (e.g., in the first direction X) the second side wall 200SW2 than the first side wall 200SW1 of the first semiconductor chip stack 200. In an embodiment, the first input/output bump pad 211 that is in direct contact with the first input/output signal bump 215 may be disposed to be closer to (e.g., in the first direction X) the second side wall 200SW2 than the first side wall 200SW1 of the first semiconductor chip stack 200.

The size of the first upper wire bonding pad 221 may be greater than the size of the first input/output bump pad 211. For example, in the first direction X, the width W221a of the first upper wire bonding pad 221 may be greater than the width W211 of the first input/output bump pad.

In an embodiment, the first upper chip 220 may receive or output signals through the first upper wire bonding pad 221, the first wire 225, the lower wire bonding pad 121b, and the second input/output signal ball 141b which are connected to each other. For example, the first upper chip 220 may receive or output data through the first upper wire bonding pad 221, the first wire 225, the lower wire bonding pad 121b, and the second input/output signal ball 141b. As another example, a command/address signal may be provided to the first upper chip 220 through the first upper wire bonding pad 221, the first wire 225, the lower wire bonding pad 121b, and the second input/output signal ball 141b.

In an embodiment, in the first direction X, the first input/output signal bump 215 may be disposed to be closer to the central portion CT than the first upper wire bonding pad 221. The first input/output signal bump 215 connected to the first input/output signal ball 141a may be disposed to be closer (e.g., in the first direction X) to the central portion CT than the first upper wire bonding pad 221 connected to the second input/output signal ball 141b.

In an embodiment, the first input/output signal bump 215 may be disposed to be closer to the first input/output signal ball 141a than to the second input/output signal ball 141b. The first upper wire bonding pad 221 may be disposed to be closer to the second input/output signal ball 141b than to the first input/output signal ball 141a.

The first upper wire bonding pad 221 may be connected to the first upper redistribution layer 222. For example, in an embodiment the first upper wire bonding pad 221 may be in direct contact with the first upper redistribution layer 222. The first upper redistribution layer 222 may be disposed on the upper face (e.g., a top surface) of the first semiconductor chip stack 200. The first upper redistribution layer 222 may be disposed on the upper face of the first upper chip 220.

In an embodiment, in the first direction X, an extending length of the first upper redistribution layer 222 may be greater than an extending length of the first upper wire bonding pad 221. In the second direction Y, a width W221b of the first upper wire bonding pad 221 may be greater than a width W222 of the first upper redistribution layer.

In an embodiment, an upper face (e.g., a top surface) of the first upper redistribution layer 222 may be coplanar (e.g., in the third direction Z) with an upper face (e.g., a top surface) of the first upper wire bonding pad 221. Although FIGS. 4 and 5 only show that the first upper redistribution layer 222 is disposed on the same layer as the first upper wire bonding pad 221, embodiments of the present disclosure are not necessarily limited thereto. For example, in an embodiment the first upper redistribution layer 222 may extend in the lower part of the first upper wire bonding pad 221 and a portion of the first upper wire bonding pad 221 may be disposed on the first upper redistribution layer 222.

Although FIGS. 4 and 5 only show that the first upper wire bonding pad 221 of the first upper chip 220 is connected to the second input/output signal ball 141b, embodiments of the present disclosure are not necessarily limited thereto. For example, in an embodiment the first upper wire bonding pad 221 may be connected to the first stack power ball 142 through the first wire 225 and the lower wire bonding pad 121b. Power may be provided to the first upper chip 220 through the first upper wire bonding pad 221, the first wire 225, the lower wire bonding pad 121b and the first stack power ball 142.

The second semiconductor chip stack 300 may include a plurality of semiconductor chips. For example, in an embodiment he second semiconductor chip stack 300 may include a second lower chip 310 and a second upper chip 320. However, embodiments of the present disclosure are not necessarily limited thereto and the number of semiconductor chips included in the second semiconductor chip stack 300 may vary. The second lower chip 310 and the second upper chip 320 may be sequentially stacked on the package substrate 100 (e.g., in the third direction Z). The second upper chip 320 may be disposed on the second lower chip 310. For example, a lower surface of the second upper chip 320 may be disposed on an upper surface of the second lower chip 310. In an embodiment, the second semiconductor chip stack 300 may include a field programmable gate array (FPGA).

In an embodiment, the second lower chip 310 and the second upper chip 320 may include memory chips. For example, the second lower chip 310 and the second upper chip 320 may include a volatile memory chip such as a DRAM.

The side walls of the second lower chip 310 and the second upper chip 320 may be aligned with each other. For example, the second lower chip 310 and the second upper chip 320 may have the same width (e.g. length in the first direction X) as each other.

A second adhesive layer 350 may be disposed between the second lower chip 310 and the second upper chip 320. The second adhesive layer 350 may serve to insulate the second lower chip 310 and the second upper chip 320 from each other. For example, in an embodiment the second adhesive layer 350 may be a DAF (Direct Adhesive Film). In an embodiment, the second adhesive layer 350 may be substantially the same as the first adhesive layer 250. Therefore, a description of the second adhesive layer 350 will not be provided for economy of explanation.

A second input/output signal bump 315 and a second power bump 316 may be disposed between the second lower chip 310 and the package substrate 100 (e.g., in the third direction X).

In an embodiment, the second lower chip 310 may receive or output signals through the second input/output signal bump 315, the lower bump bonding pad 121a, and the second input/output signal ball 143a which are connected to each other. For example, the second lower chip 310 may receive or output data through the second input/output signal bump 315, the lower bump bonding pad 121a, and the second input/output signal ball 143a which are connected to each other. As another example, a command/address signal may be provided to the second lower chip 310 through the second input/output signal bump 315, the lower bump bonding pad 121a, and the second input/output signal ball 143a which are connected to each other.

In an embodiment, power may be provided to the second lower chip 310 through the second power bump 316, the lower bump bonding pad 121a and the second stack power ball 144.

The second upper chip 320 may include a second upper wire bonding pad 321. The second upper wire bonding pad 321 may be disposed on the upper face (e.g., a top surface) of the second upper chip 320.

The second upper wire bonding pad 321 may be connected to the second wire 325. In an embodiment, the second wire 325 may be in direct contact with the upper face (e.g., top surface) of the second upper wire bonding pad 321. The second upper wire bonding pad 321 may be connected to the lower wire bonding pad 121b through the second wire 325. The second upper wire bonding pad 321 may be electrically connected to the fourth input/output signal ball 143b through the second wire 325 and the lower wire bonding pad 121b.

In an embodiment, the second upper chip 320 may receive or output signals through the second upper wire bonding pad 321, the second wire 325, the lower wire bonding pad 121b, and the fourth input/output signal ball 143b which are connected to each other. For example, the second upper chip 320 may receive or output data through the second upper wire bonding pad 321, the second wire 325, the lower wire bonding pad 121b, and the fourth input/output signal ball 143b. As another example, a command/address signal may be provided to the second upper chip 320 through the second upper wire bonding pad 321, the second wire 325, the lower wire bonding pad 121b, and the fourth input/output signal ball 143b.

In an embodiment, in the first direction X, the second input/output signal bump 315 may be disposed to be closer to the central portion CT than the second upper wire bonding pad 321. The second input/output signal bump 315 connected to the third input/output signal ball 143a may be disposed to be closer to the central portion CT (e.g., in the first direction X) than the second upper wire bonding pad 321 connected to the fourth input/output signal ball 143b.

In an embodiment, the second input/output signal bump 315 may be disposed to be closer to the third input/output signal ball 143a than to the fourth input/output signal ball 143b. The second upper wire bonding pad 321 may be disposed to be closer to the fourth input/output signal ball 143b than to the third input/output signal ball 143a.

In an embodiment, the first input/output signal bump 215 and the second input/output signal bump 315 may be disposed to be closer to the central portion CT than the first upper wire bonding pad 221 and the second upper wire bonding pad 321. In the first direction X, the first input/output signal bump 215 and the second input/output signal bump 315 may be spaced apart from each other by a first distance D1. In the first direction X, the first upper wire bonding pad 221 and the second upper wire bonding pad 321 may be spaced apart from each other by a second distance D2. In an embodiment, the first distance D1 may be less than the second distance D2.

The second upper wire bonding pad 321 may be connected to the second upper redistribution layer 322. For example, in an embodiment the second upper wire bonding pad 321 may be in direct contact with the second upper redistribution layer 322. The second upper redistribution layer 322 may be disposed on the upper face (e.g., a top surface) of the second semiconductor chip stack 300. The second upper redistribution layer 322 may be disposed on the upper face (e.g., a top surface) of the second upper chip 320.

In an embodiment, in the first direction X, the extending length of the second upper redistribution layer 322 may be greater than the extending length of the second upper wire bonding pad 321. In an embodiment, the second direction Y, the width of the second upper wire bonding pad 321 may be greater than the width of the second upper redistribution layer 322.

An upper face of the second upper redistribution layer 322 may be coplanar (e.g., in the third direction Z) with an upper face of the second upper wire bonding pad 321. Although the second upper redistribution layer 322 is shown in FIGS. 4 and 5 as being disposed only on the same layer as the second upper wire bonding pad 321, embodiments of the present disclosure are not necessarily limited thereto. For example, in an embodiment the second upper redistribution layer 322 may extend in the lower part of the second upper wire bonding pad 321 and a portion of the second upper wire bonding pad 321 may be disposed above the second upper redistribution layer 322.

Although FIGS. 4 and 5 only show that the second upper wire bonding pad 321 of the second upper chip 320 is connected to the fourth input/output signal ball 143b, embodiments of the present disclosure are not necessarily limited thereto. For example, in an embodiment the second upper wire bonding pad 321 may be connected to the second stack power ball 144 through the second wire 325 and the lower wire bonding pad 121b. In an embodiment, power may be provided to the second upper chip 320 through the second upper wire bonding pad 321, the second wire 325, the lower wire bonding pad 121b and the second stack power ball 144.

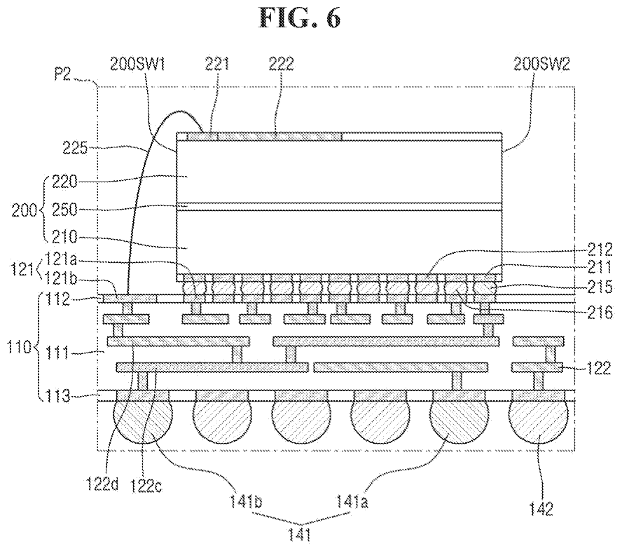

FIG. 6 is a diagram for explaining a semiconductor package according to some embodiments. For convenience of description, the description will focus on elements that are different from those described with reference to FIGS. 1 to 5.

Referring to FIG. 6, in an embodiment the first input/output signal bump 215 may be connected to the second input/output signal ball 141b. The first input/output signal bump 215 may be connected to the second input/output signal ball 141b through the first connection wiring 122c. The second input/output signal ball 141b may be disposed farther from the first input/output signal bump 215 than the first input/output signal ball 141a. Therefore, in a embodiment in which the first input/output signal bump 215 is connected to the second input/output signal ball 141b as shown in FIG. 6, the first connection wiring 122c may be relatively longer than in an embodiment in which the first input/output signal bump 215 is connected to the first input/output signal ball 141a as shown in FIGS. 1-5.

In an embodiment, the lower wire bonding pad 121b may be connected to the first input/output signal ball 141a. The lower wire bonding pad 121b may be connected to the first input/output signal ball 141a through the second connection wiring 122d. In an embodiment, the first input/output signal ball 141a may be disposed farther from the lower wire bonding pad 121b than the second input/output signal ball 141b. Therefore, in an embodiment in which the lower wire bonding pad 121b is connected to the first input/output signal ball 141a as shown in FIG. 6, the second connection wiring 122d may be relatively longer than in an embodiment in which the lower wire bonding pad 121b is connected to the second input/output signal ball 141b as shown in FIGS. 4-5.

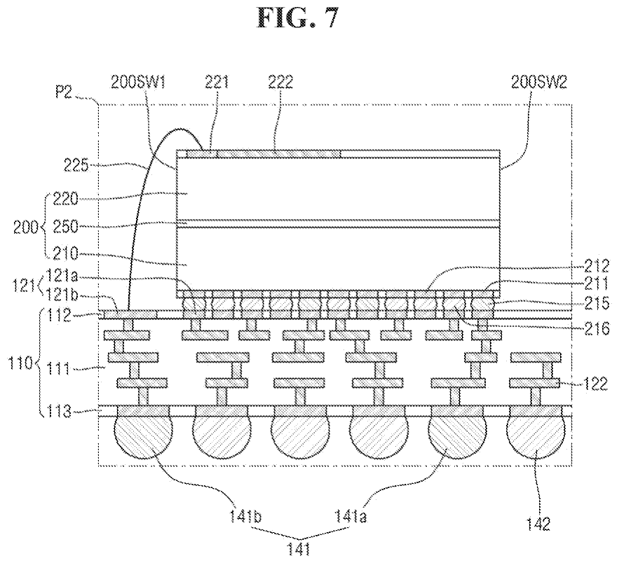

FIG. 7 is a diagram for explaining a semiconductor package according to some embodiments. For convenience of description, the description will focus on elements that are different from those described with reference to FIGS. 1 to 5.

Referring to FIG. 7, a plurality of first input/output signal bumps 215 may be disposed between the power bump bonding pad 121a and the first input/output bump pad 211 of the first semiconductor chip stack 200. The plurality of first input/output signal bumps 215 may be disposed to be spaced apart from the first power bump 216. In an embodiment, the plurality of first input/output signal bumps 215 may be connected to the first stack input/output signal ball 141 through the first wiring 122.

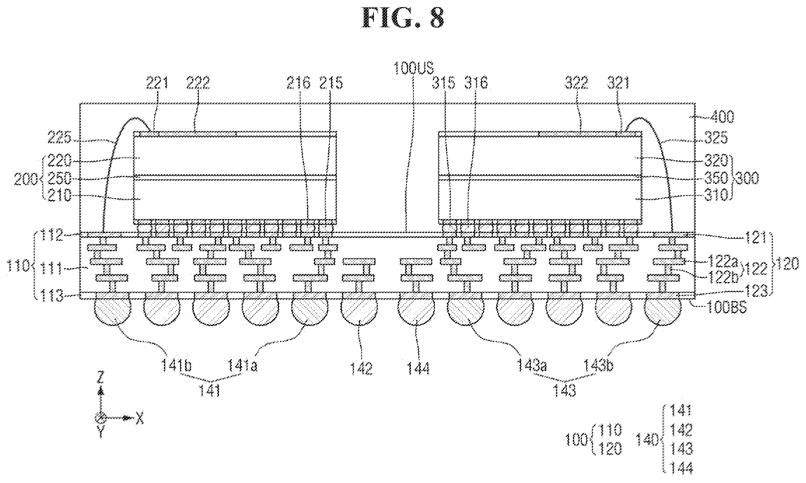

FIG. 8 is a diagram for explaining a semiconductor package according to some embodiments. For convenience of description, the description will focus on elements that are different from those described with reference to FIGS. 1 to 5.

Referring to FIG. 8, the semiconductor package according to some embodiments may include a molding film 400. The molding film 400 may be disposed on the package substrate 100. The molding film 400 may cover the upper face 100US of the package substrate.

The molding film 400 may cover the first semiconductor chip stack 200 and the second semiconductor chip stack 300 on the package substrate 100. For example, in an embodiment the molding film 400 may surround the first wire 225 and the second wire 325. The first wire 225 and the second wire 325 may extend inside the molding film 400.

The molding film 400 may be disposed between the first semiconductor chip stack 200 and the package substrate 100. The molding film 400 may fill between the first input/output signal bump 215 and the first power bump 216, between the first semiconductor chip stack 200 and the package substrate 100.

The molding film 400 may be disposed between the second semiconductor chip stack 300 and the package substrate 100. The molding film 400 may fill between the second input/output signal bump 315 and the second power bump 316, between the second semiconductor chip stack 300 and the package substrate 100.

In an embodiment, the molding film 400 may include an insulating material. For example, the molding film 400 may include a thermosetting resin such as epoxy resin, or a thermoplastic resin such as polyimide. As another example, the molding film 400 may include an insulating polymer material such as an EMC (Epoxy Molding Compound). However, embodiments of the present disclosure are not necessarily limited thereto.

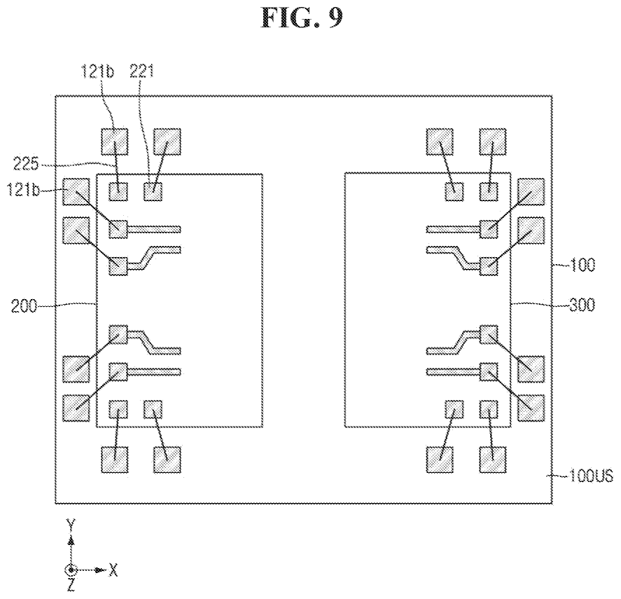

FIG. 9 is a diagram for explaining a semiconductor package according to some embodiments. For convenience of description, the description will focus on elements that are different from those described with reference to FIGS. 1 to 5.

Referring to FIG. 9, the lower wire bonding pads 121b may be disposed to be spaced apart from each other in the first direction X and the second direction Y. The lower wire bonding pads 121b may be arranged to surround the corners of the first semiconductor chip stack 200 and the corners of the second semiconductor chip stack 300.

The first upper wire bonding pads 221 may be disposed to be spaced apart from each other in the first direction X on the upper face (e.g., a top surface) of the first upper chip 220. The first upper wire bonding pad 221 may be disposed at the corners of the upper face of the first upper chip 220.

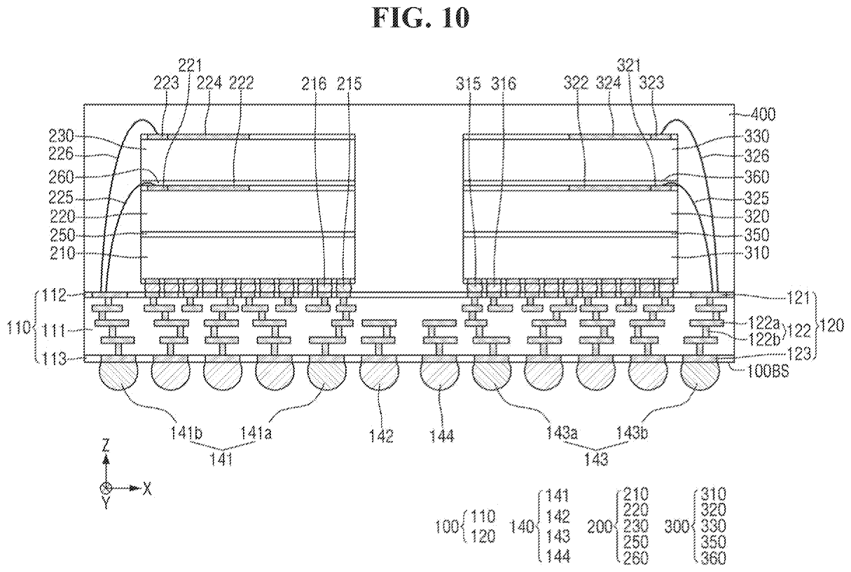

FIG. 10 is a diagram for explaining a semiconductor package according to some embodiments. For convenience of description, the description will focus on elements that are different from those described with reference to FIGS. 1 to 5.

In an embodiment the first semiconductor chip stack 200 may include a first chip 210, a second chip 220, a third chip 230, a first adhesive layer 250 and a third adhesive layer 260. The first chip 210 and the second chip 220 of FIG. 10 may correspond to the first lower chip 210 and the first upper chip 220 described with reference to embodiments shown in FIGS. 1 to 5.

The first chip 210, the second chip 220 and the third chip 230 may be sequentially stacked on the package substrate 100 (e.g., in the third direction Z). The first adhesive layer 250 may be disposed between the first chip 210 and the second chip 220 (e.g., in the third direction Z). The third adhesive layer 260 may be disposed between the second chip 220 and the third chip 230 (e.g., in the third direction Z).

A portion of the first wire 225 may be disposed in the third adhesive layer 260. In an embodiment, the second chip 220 may be connected to the second input/output signal ball 141b or the first stack power ball 142 through the first wire 225.

The third chip 230 may be connected to the second input/output signal ball 141b or the first stack power ball 142 through the third wire 226. The third wire 226 may be connected to the third upper wire bonding pad 223. The third upper wire bonding pad 223 may be connected to the third upper redistribution layer 224. The first wire 225 and the third wire 226 may be connected to the same lower wire bonding pad (121b of FIG. 5).

In an embodiment, the second semiconductor chip stack 300 may include a fourth chip 310, a fifth chip 320, a sixth chip 330, a second adhesive layer 350 and a fourth adhesive layer 360. The fourth chip 310 and the fifth chip 320 of FIG. 10 may correspond to the second lower chip 310 and the second upper chip 320 described with reference to embodiments shown in FIGS. 1 to 5.

The fourth chip 310, the fifth chip 320 and the sixth chip 330 may be sequentially stacked on the package substrate 100 (e.g., in the third direction Z). The second adhesive layer 350 may be disposed between the fourth chip 310 and the fifth chip 320 (e.g., in the third direction Z). The fourth adhesive layer 360 may be disposed between the fifth chip 320 and the sixth chip 330 (e.g., in the third direction Z).

A portion of the second wire 325 may be disposed in the fourth adhesive layer 360. The fifth chip 320 may be connected to the fourth input/output signal ball 143b or the second stack power ball 144 through the second wire 325.

In an embodiment, the sixth chip 330 may be connected to the fourth input/output signal ball 143b or the second stack power ball 144 through the fourth wire 326. The fourth wire 326 may be connected to the fourth upper wire bonding pad 323. The fourth upper wire bonding pad 323 may be connected to the fourth upper redistribution layer 324. The second wire 325 and the fourth wire 326 may be connected to the same lower wire bonding pad (121b of FIG. 5).

In concluding the detailed description, those skilled in the art will appreciate that many variations and modifications may be made to the described embodiments without substantially departing from the principles of the present disclosure. Therefore, the described embodiments of the present disclosure are used in a generic and descriptive sense only and not for purposes of limitation.

What is claimed is:

1. A semiconductor package comprising:
a package substrate;
a lower chip disposed on the package substrate;
an upper chip disposed on the lower chip;
an input/output signal bump disposed between the lower chip and the package substrate, the input/output signal bump receives and outputs a signal to and from the lower chip;
a wire bonding pad disposed on an upper face of the upper chip, wherein a wire is connected to the wire bonding pad;
a first input/output signal ball disposed on a lower face of the package substrate, the first input/output signal ball receives and outputs the signal to and from the lower chip, the first input/output signal ball is connected to the input/output signal bump; and
a second input/output signal ball disposed on the lower face of the package substrate, the second input/output signal ball receives and outputs a signal to and from the upper chip, the second input/output signal ball is electrically connected to the wire bonding pad,
wherein the first input/output signal ball and the second input/output signal ball are spaced apart from each other in a first direction, the input/output signal bump is disposed closer to the first input/output signal ball than the second input/output signal ball, and
the wire bonding pad is disposed closer to the second input/output signal ball than the first input/output signal ball in the first direction.

2. The semiconductor package of claim 1,
wherein the lower chip has a same width as the upper chip in the first direction.

3. The semiconductor package of claim 1, further comprising:
an adhesive layer disposed between the lower chip and the upper chip.

4. The semiconductor package of claim 1, further comprising:
a power ball disposed on the lower face of the package substrate, the power ball is spaced apart from the first input/output signal ball and the second input/output signal ball in the first direction; and
a power bump disposed between the lower chip and the package substrate, the power bump is spaced apart from the input/output signal bump in the first direction and is electrically connected to the power ball.

5. The semiconductor package of claim 4,
wherein a level of a signal provided to the power ball is greater than a level of a signal provided to the first input/output signal ball and the second input/output signal ball.

6. The semiconductor package of claim 1, further comprising:
a redistribution layer disposed on the upper face of the upper chip, the redistribution layer is connected to the wire bonding pad.

7. The semiconductor package of claim 6,
wherein an extending length of the redistribution layer in the first direction is greater than an extending length of the wire bonding pad in the first direction.

8. The semiconductor package of claim 6,
wherein a width of the wire bonding pad in a second direction intersecting the first direction is greater than a width of the redistribution layer in the second direction.

9. The semiconductor package of claim 1, further comprising:
an input/output bump pad disposed on a lower face of the lower chip, the input/output bump pad faces the package substrate and is in direct contact with the input/output signal bump,
wherein a width of the wire bonding pad in the first direction is greater than a width of the input/output bump pad in the first direction.

10. The semiconductor package of claim 1, wherein:
the lower chip and the upper chip include a first side wall and a second side wall opposite to each other in the first direction;
the wire bonding pad is closer to the first side wall than the second side wall; and
the input/output signal bump is closer to the second side wall than the first side wall.

11. The semiconductor package of claim 1, further comprising:
a molding film disposed on the package substrate, the molding film covers the lower chip and the upper chip.

12. A semiconductor package comprising:
a package substrate;
a first semiconductor chip stack disposed on the package substrate, the first semiconductor chip stack including a first lower chip and a first upper chip sequentially stacked;
a second semiconductor chip stack disposed on the package substrate and spaced apart from the first semiconductor chip stack, the second semiconductor chip stack including a second lower chip and a second upper chip sequentially stacked;
a first wire bonding pad disposed on the first upper chip, the first wire bonding pad is electrically connected to the package substrate by a wire; and
an input/output signal bump disposed between the first semiconductor chip stack and the package substrate, the input/output signal bump receives and outputs input/output signals to and from the first lower chip,
wherein the package substrate includes a first input/output signal ball disposed on a lower face of the package substrate, the first input/output signal ball is electrically connected to the input/output signal bump,
wherein the package substrate further includes a second input/output signal ball disposed on the lower face of the package substrate and spaced apart from the first input/output signal ball, the second input/output signal ball is electrically connected to the wire,
the first semiconductor chip stack includes a first side face facing the second semiconductor chip stack, and a second side face opposite to the first side face,
the first input/output signal ball is disposed closer to the first side face than the second side face, and
the second input/output signal ball is disposed closer to the second side face than the first side face.

13. The semiconductor package of claim 12, further comprising:
an adhesive layer disposed between the first lower chip and the first upper chip.

14. The semiconductor package of claim 12, further comprising:
a power ball disposed on the lower face of the package substrate, the power ball provides power to the first lower chip or the first upper chip;
a power bump disposed between the first semiconductor chip stack and the package substrate, the power bump is electrically connected to the power ball; and
a second wire bonding pad disposed on the first upper chip ands spaced apart from the first wire bonding pad, the second wire bonding pad is electrically connected to the power ball.

15. The semiconductor package of claim 12, wherein:
a distance between the second side face and the first wire bonding pad is less than a distance between the second side face and the input/output signal bump.

16. The semiconductor package of claim 15, wherein:
the input/output signal bump is disposed closer to the first side face than the second side face; and
the first wire bonding pad is disposed closer to the second side face than the first side face.

17. The semiconductor package of claim 12, further comprising:
a molding film disposed on the package substrate, the molding film covers the first semiconductor chip stack and the second semiconductor chip stack.

18. A semiconductor package comprising:
a package substrate;
a first semiconductor chip stack disposed on the package substrate, the first semiconductor chip stack including a first lower chip and a first upper chip sequentially stacked;
a second semiconductor chip stack disposed on the package substrate and spaced apart from the first semiconductor chip stack, the second semiconductor chip stack including a second lower chip and a second upper chip sequentially stacked;
a first wire bonding pad disposed on the first upper chip, the first wire bonding pad is electrically connected to the package substrate by a first wire;
a first input/output signal bump disposed between the first semiconductor chip stack and the package substrate, the first input/output signal bump receives and outputs an input/output signal to and from the first lower chip;
a second wire bonding pad disposed on the second upper chip, the second wire bonding pad is electrically connected to the package substrate by a second wire;
a second input/output signal bump disposed between the second semiconductor chip stack and the package substrate, the second input/output signal bump receives and outputs an input/output signal to and from the second upper chip;
a first input/output signal ball disposed on a lower face of the package substrate, the first input/output signal ball is connected to the first input/output signal bump;
a second input/output signal ball disposed on the lower face of the package substrate, the second input/output signal ball is connected to the first wire bonding pad;
a third input/output signal ball disposed on the lower face of the package substrate, the third input/output signal ball is connected to the second input/output signal bump;
a fourth input/output signal ball disposed on the lower face of the package substrate, the fourth input/output signal ball is connected to the second wire bonding pad; and
a power ball disposed on the lower face of the package substrate, the power ball provides power to the first semiconductor chip stack or the second semiconductor chip stack,
wherein a distance between the first input/output signal bump and the second input/output signal bump is less than a distance between the first wire bonding pad and the second wire bonding pad.

19. The semiconductor package of claim 18,
wherein a distance between the first input/output signal ball and the third input/output signal ball is less than a distance between the second input/output signal ball and the fourth input/output signal ball.

20. The semiconductor package of claim 18,
wherein the first semiconductor chip stack includes a field programmable gate array (FPGA).
